(19) United States
(12) Patent Application Publication
(10) Pub. No.: US 2024/0274451 A1
(43) Pub. Date: Aug. 15, 2024

(54) SUBSTRATE PROCESSING APPARATUS AND SUBSTRATE PROCESSING METHOD

(71) Applicant: SCREEN Holdings Co., Ltd., Kyoto (JP)

(72) Inventors: Saki MIYAGAWA, Kyoto (JP); Masanobu SATO, Kyoto (JP); Hiroshi HORIGUCHI, Kyoto (JP)

(21) Appl. No.: 18/691,844

(22) PCT Filed: Sep. 12, 2022
(86) PCT No.: PCT/JP2022/034062

§ 371 Date: Mar. 13, 2024

(30) Foreign Application Priority Data
Sep. 14, 2021 (JP) 2021-149463

(51) Int. Cl. H01L 21/67; H01L 21/66

(52) U.S. Cl. CPC H01L 21/67253; H01L 22/26

(57) ABSTRACT

Substrate processing apparatus includes a substrate holder, a processing liquid supply, a component abundance meter, and a controller including: a temporal-change-acquiring section that acquires a temporal change in abundance of a specific component based on the abundance of the specific component of the substrate measured through a component abundance meter during a specific time period, before a processing liquid supply starts and then ends supply of the processing liquid to the substrate, within a processing liquid supply period; a prediction-line-creating section that creates a prediction line, which predicts a temporal change in the abundance of the specific component of the substrate after the specific time period, based on a temporal change in the abundance of the specific component acquired by the temporal-change-acquiring section; and a processing-condition-changing section that changes a substrate processing condition based on the prediction line before the supply of the processing liquid is stopped.

### TECHNICAL FIELD

The present invention relates to a substrate processing apparatus and a substrate processing method.

### BACKGROUND ART

Substrate processing apparatuses that process a substrate are known. The substrate processing apparatuses are suitably used for processing semiconductor substrates. A typical substrate processing apparatus processes a substrate using a processing liquid such as a chemical liquid.

Substrate processing being considered is performed by measuring the amount of a component present on a substrate on the spot to confirm the component of interest while processing the substrate with a processing liquid (Patent Literature 1). A substrate processing apparatus in Patent Literature 1 measures abundance of a component contained in a processing liquid film by emitting infrared light toward the substrate to receive the infrared light reflected back therefrom.

### CITATION LIST

### Patent Literature

### Patent Literature 1

JP2020-118698 A

### SUMMARY OF INVENTION

### Technical Problem

A typical substrate processing condition is set with margins taken into consideration in order to equalize respective characteristics of a plurality of substrates. For example, time to supply a processing liquid is often set to be longer by the margin to be taken into account than time required to process an average substrate. As a result, substrates with uniform characteristics can be manufactured in large quantities according to a predetermined recipe.

The substrate processing apparatus in Patent Literature 1 can measure a component contained in a processing liquid film on a substrate by infrared light reflected back from a substrate as a result of emitting the infrared light toward the substrate. However, the component contained in the processing liquid film may be reduced to almost zero. In this case, the substrate processing apparatus in Patent Literature 1 cannot sufficiently detect differences in the infrared light reflected back. It is consequently difficult to accurately measure whether the component contained in the processing liquid film on the substrate has been sufficiently removed. For this reason, a substrate processing condition needs to be set with margins taken into consideration which, however focusing on individual substrates, causes excessive processing to be performed on the substrates.

The present invention has been achieved in view of the above circumstances, and an object thereof is to provide a substrate processing apparatus and a substrate processing method, capable of processing a substrate under a substrate processing condition according to characteristics of the substrate.

### Solution to Problem

A substrate processing apparatus according to an aspect of the present invention includes a substrate holder, a processing liquid supply, a component abundance meter, and a controller. The substrate holder holds a substrate. The processing liquid supply supplies a processing liquid to the substrate. The component abundance meter measures abundance of a specific component of the substrate. The controller controls the substrate holder, the processing liquid supply, and the component abundance meter. The controller includes a temporal-change-acquiring section, a prediction-line-creating section, and a processing-condition-changing section. The temporal-change-acquiring section acquires a temporal change in the abundance of the specific component based on the abundance of the specific component of the substrate measured through the component abundance meter during a specific period of time within a processing liquid supply period. The processing liquid supply period is a period of time from start to end of supply of the processing liquid to the substrate by the processing liquid supply. The prediction-line-creating section creates a prediction line based on a temporal change in the abundance of the specific component acquired by the temporal-change-acquiring section. The prediction line predicts a temporal change in the abundance of the specific component of the substrate after the specific period of time within the processing liquid supply period. The processing-condition-changing section changes a substrate processing condition, under which a specific substrate that is the substrate or a substrate is processed, based on the prediction line before the supply of the processing liquid is stopped.

In an embodiment, the component abundance meter measures the abundance of the specific component of the substrate using infrared light.

In an embodiment, the processing-condition-changing section changes the substrate processing condition, under which the specific substrate is processed, based on a substrate processing condition and processing results with respect to a substrate to be learned.

In an embodiment, the processing-condition-changing section changes the substrate processing condition, under which the specific substrate is processed, through a trained model. The trained model is built through machine learning from learning data that contains the substrate processing condition and the processing results with respect to the substrate to be learned. Here, the substrate processing condition and the processing results are associated with each other.

In an embodiment, the processing-condition-changing section changes the processing liquid supply period, during which the processing liquid supply supplies the processing liquid, based on the temporal change in the abundance of the specific component acquired by the temporal-change-acquiring section.

In an embodiment, the processing-condition-changing section shortens the processing liquid supply period based on the temporal change in the abundance of the specific component acquired by the temporal-change-acquiring section.

In an embodiment, the processing-condition-changing section changes, based on the temporal change in the abundance of the specific component acquired by the temporal-change-acquiring section, any of: a flow rate, a concentration, and a temperature of the processing liquid for processing the specific substrate; a substrate rotation speed at which the specific substrate is rotated by the substrate holder: and the processing liquid supply period during which the processing liquid is supplied.

In an embodiment, the processing-condition-changing section changes the substrate processing condition, under which the specific substrate is processed, with the processing liquid supply continuing the supply of the processing liquid.

In an embodiment, the processing-condition-changing section changes substrate processing condition, under which a different substrate is processed, based on the temporal change in the abundance of the specific component acquired by the temporal-change-acquiring section. The different substrate is different from the substrate from which the temporal-change-acquiring section has acquired the abundance of the specific component.

A substrate processing method according to another aspect of the present invention includes: measuring abundance of a specific component of a substrate during a specific period of time within a processing liquid supply period, the processing liquid supply period being a period of time from start to end of supply of a processing liquid to the substrate; acquiring a temporal change in the abundance of the specific component based on the abundance of the specific component of the substrate measured in the measuring; creating a prediction line based on a temporal change in the abundance of the specific component acquired in the acquiring, the prediction line predicting a temporal change in the abundance of the specific component of the substrate after the specific period of time within the processing liquid supply period; and changing a substrate processing condition, under which a specific substrate that is the substrate or a substrate is processed, based on the prediction line before the supply of the processing liquid is stopped.

### Advantageous Effects of Invention

The present invention can process a substrate under a substrate processing condition according to the characteristics of the substrate.

### BRIEF DESCRIPTION OF DRAWINGS

FIG. 1 is a schematic diagram of a substrate processing system including a substrate processing apparatus according to the present embodiment.

FIG. 2 is a schematic diagram of a substrate processing apparatus according to the present embodiment.

FIG. 3 is a block diagram of a substrate processing apparatus according to the present embodiment.

FIG. 4 is a flow diagram of a substrate processing method according to the present embodiment.

FIGS. 5A to 5D schematically illustrate a substrate processing method according to the present embodiment.

FIGS. 6A to 6C schematically illustrate a substrate processing method according to the present embodiment.

FIGS. 7A to 7D schematically illustrate a temporal change in the abundance of a specific component and a substrate processing condition in a substrate processing method according to the present embodiment.

FIGS. 8A to 8D schematically illustrate a temporal change in the abundance of a specific component and a substrate processing condition in a substrate processing method according to the present embodiment.

FIGS. 9A to 9D schematically illustrate a temporal change in the abundance of a specific component and a processing liquid supply period in a substrate processing method according to the present embodiment.

FIGS. 10A to 10D schematically illustrate a temporal change in the abundance of a specific component and a processing liquid supply period in a substrate processing method according to the present embodiment.

FIG. 11 is a block diagram of a substrate processing apparatus according to the present embodiment.

FIG. 12 is a schematic diagram of a substrate processing learning system including a substrate processing apparatus according to the present embodiment.

FIG. 13A is a schematic diagram depicting lots of a plurality of substrates in a substrate processing method according to the present embodiment, and FIGS. 13B to 13D schematically illustrate a temporal change in the abundance of a specific component and a substrate processing condition in a substrate processing method according to the present embodiment.

### DESCRIPTION OF EMBODIMENTS

Embodiments of a substrate processing apparatus and a substrate processing method according to an aspect of the present invention will be described below with reference to the drawings. Note that elements which are the same or equivalent are labeled with the same reference signs in the drawings and description thereof is not repeated. In the specification, in order to facilitate understanding of the invention, an X-axis, a Y-axis, and a Z-axis that are orthogonal to each other may be described. Typically, the X- and Y-axes are parallel to the horizontal direction, and the Z-axis is parallel to the vertical direction.

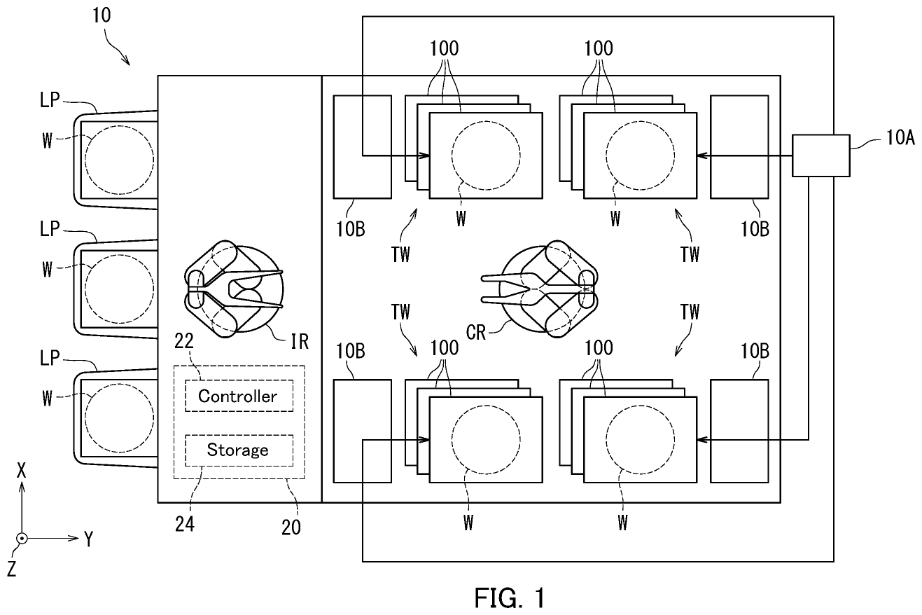

First, a substrate processing system 10 including a substrate processing apparatus 100 according to the present embodiment will be described with reference to FIG. 1. FIG. 1 is a schematic plan view of the substrate processing system 10.

As depicted in FIG. 1, the substrate processing system 10 includes a plurality of substrate processing apparatuses 100. Each substrate processing apparatus 100 processes a substrate W. The substrate processing apparatus 100 processes the substrate W so as to perform at least one of steps that include etching, surface finishing, property imparting, processing film forming, and removing and cleaning at least part of a film.

The substrate W is employed as a semiconductor substrate. The substrate W includes a semiconductor wafer. For example, the substrate W has a shape like a disk. Here, the substrate processing apparatus 100 processes substrates W one by one.

As depicted in FIG. 1, in addition to the substrate processing apparatuses 100, the substrate processing system 10 includes a fluid cabinet 10A, fluid boxes 10B, load ports LP, an indexer robot IR, a center robot CR, and a control device 20. The control device 20 controls the load ports LP, the indexer robot IR, the center robot CR, and the substrate processing apparatuses 100.

Each of the load ports LP accommodates a plurality of substrates W in a pile. The indexer robot IR conveys a substrate W between the load ports LP and the center robot CR. Note that the apparatus may be configured so that an installation stand (path) on which a substrate W is temporarily placed is provided between the indexer robot IR and the center robot CR, whereby the substrate W is conveyed indirectly between the indexer robot IR and the center robot CR via the installation stand. The center robot CR conveys a substrate W between the indexer robot IR and the substrate processing apparatuses 100. Each of the substrate processing apparatuses 100 discharges a liquid onto a substrate W to process the substrate W. The liquid includes a processing liquid. Alternatively, the liquid may include other liquids. The fluid cabinet 10A holds the liquid. Note that the fluid cabinet 10A may hold gas.

The plurality of substrate processing apparatuses 100 forms a plurality of towers TW (four towers TW in FIG. 1) arranged to surround the center robot CR in plan view. Each tower TW includes a plurality of substrate processing apparatuses 100 (three substrate processing apparatuses 100 in FIG. 1) stacked one above the other. Each of the fluid boxes 10B corresponds to towers TW. The liquid in each fluid cabinet 10A is supplied, via a fluid box 10B of the fluid boxes 10B, to all the substrate processing apparatuses 100 included in the tower TW corresponding to the fluid box 10B. The gas in each fluid cabinet 10A is also supplied, via a fluid box 10B of the fluid boxes 10B, to all the substrate processing apparatuses 100 included in the tower TW corresponding to the fluid box 10B.

The control device 20 controls various operations of the substrate processing system 10. The control device 20 includes a controller 22 and storage 24. The controller 22 includes a processor. The controller 2 includes, for example a central processing unit (CPU). Alternatively, the controller 22 may include a general-purpose arithmetic device.

The storage 24 includes main memory and auxiliary storage. Main memory is, for example, semiconductor memory. Examples of the auxiliary storage include semiconductor memory and a hard disk drive. The storage 24 may include removable media. The controller 22 executes a computer program stored in the storage 24 to perform a substrate processing operation.

The storage 24 stores data. The data contains recipe data. The recipe data contains information on a plurality of recipes. Each of the plurality of recipes defines processing contents and processing procedures for substrates W.

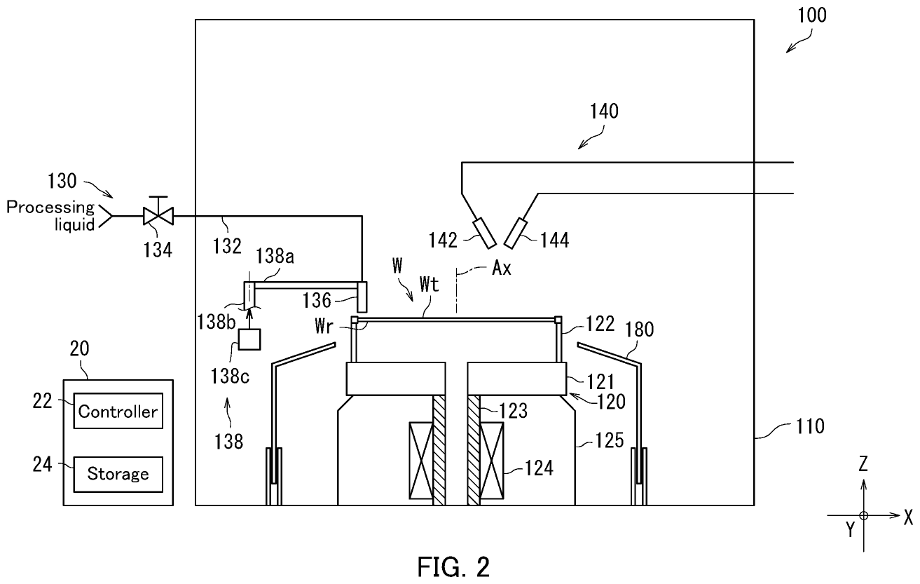

A substrate processing apparatus 100 according to the present embodiment will then be described with reference to FIG. 2. FIG. 2 is a schematic diagram of the substrate processing apparatus 100.

The substrate processing apparatus 100 includes a chamber 110, a substrate holder 120, a processing liquid supply 130, and a component abundance meter 140. The chamber 110 accommodates a substrate W. The chamber 110 accommodates the substrate holder 120, at least part of the processing liquid supply 130, and at least part of the component abundance meter 140.

The chamber 110 has a shape like a box with an internal space. The chamber 110 accommodates a substrate W. Here, the substrate processing apparatus 100 is a single-wafer type that processes substrates W one by one, and the chamber 110 accommodates one substrate W at a time. The substrate W is accommodated in the chamber 110 and processed within the chamber 110.

The substrate holder 120 holds a substrate W. The substrate holder 120 holds the substrate W horizontally so that the upper surface (front surface) Wt of the substrate W faces upward and the lower surface (back surface) Wr of the substrate W faces vertically downward. The substrate holder 120 rotates the substrate W while holding the substrate W. The upper surface Wt of the substrate W may be flattened. Alternatively, the upper surface Wt of the substrate W may be provided with a device surface, or may be provided with a pillar-shaped laminate having a recess. The substrate holder 120 rotates the substrate W while holding the substrate W.

For example, the substrate holder 120 may be a clamping type that clamps the end parts of the substrate W. Alternatively, the substrate holder 120 may have any mechanism that holds the substrate W from a side of the back surface Wr. For example, the substrate holder 120 may be of a vacuum type. In this case, the substrate holder 120 includes an upper surface and holds the substrate W horizontally by adsorbing, to the upper surface, a center portion of the back surface Wr of the substrate W. Here, the back surface Wr is a non-device forming surface. Alternatively, the substrate holder 120 may be configured by combining a vacuum type and a clamping type that brings a plurality of chuck pins into contact with the peripheral end face of the substrate W.

For example, the substrate holder 120 includes a spin base 121, a chuck member 122, a shaft 123, an electric motor 124, and a housing 125. The spin base 121 is provided with the chuck member 122. The chuck member 122 holds a substrate W. Typically, the spin base 121 is provided with a plurality of chuck members 122.

The shaft 123 is a hollow shaft. The shaft 123 has a rotation axis Ax and extends vertically along the rotation axis Ax. The spin base 121 is coupled to the upper end of the shaft 123. The substrate W is placed above the spin base 121.

The spin base 121 has a shape like a disk. The chuck member 122 supports the substrate W horizontally. The shaft 123 extends downward from the center of the spin base 121. The electric motor 124 applies rotational force to the shaft 123. The electric motor 124 rotates the shaft 123 in the rotational direction, thereby rotating the substrate W and the spin base 121 about the rotation axis Ax. The housing 125 surrounds the shaft 123 and the electric motor 124.

The processing liquid supply 130 supplies a processing liquid to the substrate W. Typically, the processing liquid supply 130 supplies the processing liquid to the upper surface Wt of the substrate W held by the substrate holder 120. Note that the processing liquid supply 130 may supply a plurality of types of processing liquids to the substrate W.

The processing liquid may be an etching liquid that etches the substrate W. Examples of the etching liquid include hydrofluoric/nitric acid (a mixture of hydrofluoric acid (HF) and nitric acid (HNO₃)), hydrofluoric acid, buffered hydrogen fluoride (BHF), ammonium fluoride, a mixture of hydrofluoric acid and ethylene glycol (HFEG), and phosphoric acid (H₃PO₄). The type of etching liquid is not particularly limited, but may be acidic or alkaline, for example.

The processing liquid may be a rinse liquid. Examples of the rinse liquid include deionized water (DIW), carbonated water, electrolytic ionized water, ozone water, ammonia water, diluted hydrochloric acid water (e.g., about 10 ppm to 100 ppm), and reinjected water (hydrogen water).

The processing liquid may be an organic solvent. Typically, the organic solvent has a higher volatility than that of the rinse liquid. Examples of the organic solvent include isopropyl alcohol (IPA), methanol, ethanol, acetone, hydrofluoroether (HFE), propylene glycol ethyl ether: PGEE), and propylene glycol monomethyl ether acetate (PGMEA).

The processing liquid supply 130 includes a pipe 132, a valve 134, a nozzle 136, and a moving mechanism 138. The pipe 132 allows a processing liquid supplied from a supply source to pass through. The valve 134 opens and closes the flow path within the pipe 132. The nozzle 136 is connected to the pipe 132. The nozzle 136 discharges the processing liquid to the upper surface Wt of the substrate W. Preferably, the nozzle 136 is configured to be movable relative to the substrate W.

The moving mechanism 138 moves the nozzle 136 in the horizontal and vertical directions. Specifically, the moving mechanism 138 includes a rotation axis directed towards the vertical direction and moves the nozzle 136 in the circumferential direction about the rotation axis. The moving mechanism 138 also moves the nozzle 136 up and down in the vertical direction.

The moving mechanism 138 includes an arm 138a, a shaft 138b, and a driver 138c. The arm 138a extends in the horizontal direction. The nozzle 136 is placed at the tip of the arm 138a. The nozzle 136 is placed at the tip of the arm 138a in a posture that allows the processing liquid to be supplied toward the upper surface Wt of the substrate W held by the chuck member 122. Specifically, the nozzle 136 is coupled to the tip of the arm 138a and projects downward from the arm 138a. The base end of the arm 138a is coupled to the shaft 138b. The shaft 138b extends in the vertical direction.

The driver 138c includes a rotating drive mechanism and an elevating drive mechanism. The rotating drive mechanism of the driver 138c rotates the shaft 138b about the rotation axis to pivot the arm 138a about the shaft 138b in the horizontal plane. As a result, the nozzle 136 moves in the horizontal plane. Specifically, the nozzle 136 moves in the circumferential direction around the shaft 138b. The rotating drive mechanism of the driver 138c includes, for example, a motor capable of forward and reverse rotation.

The elevating drive mechanism of the driver 138c moves the shaft 138b up and down in the vertical direction. The elevating drive mechanism of the driver 138c moves the shaft 138b up and down, whereby the nozzle 136 moves up and down in the vertical direction. The elevating drive mechanism of the driver 138c includes a drive source such as a motor and an elevating mechanism. The drive source drives the elevating mechanism to move the shaft 138b up and down. The elevating mechanism includes, for example, a rack and pinion mechanism or a ball screw.

The component abundance meter 140 measures the abundance of a specific component of the substrate W. The specific component may be an organic substance present in the substrate W.

For example, the component abundance meter 140 measures the abundance of the specific component of the substrate W using infrared light. The wavelength of the infrared light is 2.5 μm or more and 25 μm or less (wave number: 400 cm⁻¹ or more and 4000 cm⁻¹ or less).

For example, bonds such as C—H, C—O, C—N, and C—F in organic substances absorb specific wavelengths of infrared radiation. The amount of absorbed specific wavelengths of infrared radiation is proportional to the amount of the component having a specific bonding group. The abundance of the specific component of a substrate W can therefore be measured based on infrared radiation reflected back from the substrate W.

The component abundance meter 140 includes a light emitter 142 and a light receiver 144. The light emitter 142 emits light toward the substrate W. The light receiver 144 receives light reflected back from the substrate W toward which the light emitter 142 emits light.

The component abundance meter 140 may be movable relative to the substrate W. In a preferable example, the component abundance meter 140 is movable in the horizontal direction and/or the vertical direction according to a moving mechanism controlled by the controller 22. In the case where the component abundance meter 140 moves, the light emitter 142 and the light receiver 144 may be mutually movable independently. Alternatively, the light emitter 142 and the light receiver 144 may be movable as one unit.

The substrate processing apparatus 100 further includes a cup 180. The cup 180 collects a liquid scattered from a substrate W. The cup 180 moves up and down. For example, the cup 180 keeps a vertically risen state up to the side of the substrate W over a period of time during which the processing liquid supply 130 supplies the liquid to the substrate W. In this case, the cup 180 collects the liquid scattered from the substrate W due to the rotation of the substrate W. The cup 180 also moves vertically downward from the side of the substrate W when the period of time, during which the processing liquid supply 130 supplies the liquid to the substrate W, ends.

As described above, the control device 20 includes the controller 22 and the storage 24. The controller 22 controls the substrate holder 120, the processing liquid supply 130, the component abundance meter 140, and/or the cup 180. In one example, the controller 22 controls the electric motor 124, the valve 134, the moving mechanism 138, the light emitter 142, the light receiver 144, and/or the cup 180.

The substrate processing apparatus 100 according to the present embodiment is suitably used for manufacturing semiconductor devices including semiconductors. Typically, conductive layers and insulating layers are laminated on a base member in a semiconductor device. The substrate processing apparatus 100 is suitably used for cleaning and/or processing (e.g., etching, characteristic change) conductive layers and/or insulating layers when semiconductor devices are manufactured.

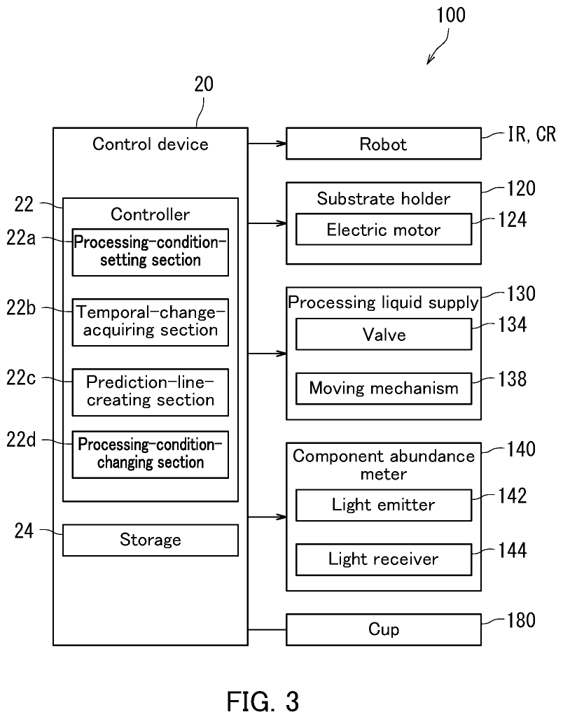

A substrate processing apparatus 100 according to the present embodiment will then be described with reference to FIGS. 1 to 3. FIG. 3 is a block diagram of the substrate processing apparatus 100.

As depicted in FIG. 3, a control device 20 controls various operations of the substrate processing apparatus 100. The control device 20 controls an indexer robot IR, a center robot CR, a substrate holder 120, a processing liquid supply 130, a component abundance meter 140, and a cup 180. Specifically, the control device 20 transmits respective control signals to the indexer robot IR, the center robot CR, the substrate holder 120, the processing liquid supply 130, the component abundance meter 140, and the cup 180, thereby controlling the indexer robot IR, the center robot CR, the substrate holder 120, the processing liquid supply 130, the component abundance meter 140, and the cup 180.

Storage 24 stores a computer program and data. The data contains recipe data. The recipe data contains information on a plurality of recipes. Each of the recipes defines processing contents, processing procedures, and a substrate processing condition for substrates W. A controller 22 executes a computer program stored in the storage 24 to perform substrate processing operations.

As described above, the storage 24 stores the computer program. The controller 22 executes the computer program, thereby functioning as a processing-condition-setting section 22a, a temporal-change-acquiring section 22b, a prediction-line-creating section 22c, and a processing-condition-changing section 22d. The controller 22 therefore includes the processing-condition-setting section 22a, the temporal-change-acquiring section 22b, the prediction-line-creating section 22c, and the processing-condition-changing section 22d.

The processing-condition-setting section 22a sets therein a substrate processing condition for processing substrates W. For example, the processing-condition-setting section 22a sets the substrate processing condition based on recipe information stored in the storage 24. The substrate processing condition includes at least one of parameters that include: a flow rate, a concentration, and a temperature of a processing liquid for processing a substrate W; a substrate rotation speed at which the substrate W is rotated by the substrate holder 120; and a processing liquid supply period during which the processing liquid is supplied.

The temporal-change-acquiring section 22b acquires a temporal change in the abundance of a specific component of the substrate W. The temporal-change-acquiring section 22b acquires the temporal change in the abundance of the specific component from the abundance of the specific component measured through the component abundance meter 140.

The prediction-line-creating section 22c creates a prediction line that predicts a temporal change in the specific component based on the temporal change in the abundance of the specific component acquired by the temporal-change-acquiring section 22b. The prediction-line-creating section 22c may create a prediction line from a predetermined relational expression based on the temporal change in the abundance of the specific component. For example, the prediction-line-creating section 22c may calculate an approximate formula that linearly interpolates the temporal change in the abundance of the specific component and then create a prediction line using the approximate formula. Alternatively, the prediction-line-creating section 22c may create a prediction line through a trained model. Here, the trained model is built through machine learning from learning data that contains a processing condition and processing results with respect to a substrate to be learned. Here, the processing condition and the processing results are associated with each other. The processing results include a temporal change in the abundance of the specific component of the substrate to be learned.

The processing-condition-changing section 22d changes the substrate processing condition based on the prediction line before the supply of the processing liquid is stopped. Typically, the substrate processing condition previously set in the processing-condition-setting section 22a is defined based on a pre-estimated temporal change in the specific component of substrates W. However, when actually processing substrates, strictly speaking, respective temporal changes of specific components of substrates W differ depending on respective characteristics of the substrates. The processing-condition-changing section 22d changing the substrate processing condition enables the substrates W to be processed under a substrate processing condition according to the characteristics of each substrate W.

The controller 22 controls the indexer robot IR to transfer a substrate W through the indexer robot IR.

The controller 22 controls the center robot CR to transfer the substrate W through the center robot CR. For example, the center robot CR receives a substrate W that has not been processed and then loads the substrate W into one of the chambers 110. The center robot CR also receives the substrate W, which has been processed, from the chamber 110, thereby unloading the substrate W.

The controller 22 controls the substrate holder 120 to start the rotation of the substrate W, change the rotation speed, and stop the rotation of the substrate W. For example, the controller 22 may change the rotation speed of the substrate holder 120 by controlling the substrate holder 120. Specifically, the controller 22 may change the rotation speed of the substrate W by changing the rotation speed of an electric motor 124 of the substrate holder 120.

The controller 22 may control a valve 134 of the processing liquid supply 130 to switch the state of the valve 134 between an open state and a closed state. Specifically, the controller 22 may control the valve 134 of the processing liquid supply 130 to open the valve 134, thereby causing the processing liquid to flow in and pass through a pipe 132 toward a nozzle 136. The controller 22 may also control the valve 134 of the processing liquid supply 130 to close the valve 134, thereby stopping the supply of the processing liquid to flow in the pipe 132 toward the nozzle 136.

The controller 22 may control a moving mechanism 138 of the processing liquid supply 130 to move the nozzle 136. Specifically, the controller 22 may control the moving mechanism 138 of the processing liquid supply 130 to move the nozzle 136 above the upper surface Wt of the substrate W. The controller 22 may also control the moving mechanism 138 of the processing liquid supply 130 to move the nozzle 136 to a retracted position away from the position above the upper surface Wt of the substrate W.

The controller 22 controls the component abundance meter 140 and then measures the abundance of the specific component of the substrate W. The controller 22 measures the abundance of the specific component of the substrate W by controlling a light emitter 142 and a light receiver 144 so that the light emitter 142 emits infrared light and the light receiver 144 receives the infrared light reflected back from the substrate W to measure the intensity of the light received. The controller 22 may control the component abundance meter 140 to move the component abundance meter 140 relative to the substrate W.

The controller 22 may control the cup 180 to move the cup 180 relative to the substrate W. Specifically, the controller 22 keeps a vertically risen state of the cup 180 up to the side of the substrate W over a period of time during which the processing liquid supply 130 supplies the liquid to the substrate W. The controller 22 also moves the cup 180 vertically downward from the side of the substrate W when the period of time during which the processing liquid supply 130 supplies the liquid to the substrate W ends.

Note that the substrate processing apparatus 100 may further include a display section (not illustrated in FIG. 3) that displays the processing status of the substrate W. For example, the display section may display the processing results of the substrate W, or may display the predicted state of the substrate W to be processed.

The substrate processing apparatus 100 according to the present embodiment is suitably used for forming semiconductor devices. For example, the substrate processing apparatus 100 is suitably used to process a substrate W used as a semiconductor device having a stacked structure. The semiconductor device is a so-called 3D structured memory (storage device). As an example, the substrate W is suitably used as NAND flash memory.

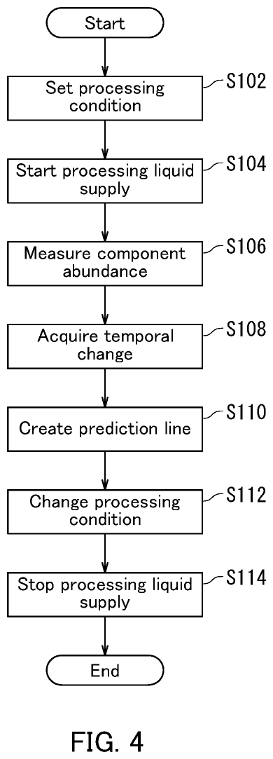

A substrate processing method according to the present embodiment will then be described with reference to FIGS. 1 to 4. FIG. 4 is a flow diagram of the substrate processing method.

As depicted in FIG. 4, Step S102 includes setting a substrate processing condition for processing a substrate W. Specifically, a processing-condition-setting section 22a sets the substrate processing condition. For example, the processing-condition-setting section 22a reads the substrate processing condition from recipes stored in storage 24 and then sets therein the substrate processing condition.

Step S104 includes starting the supply of a processing liquid according to the substrate processing condition. A processing liquid supply 130 starts the supply of the processing liquid to the substrate W under the control of a controller 22. Note that when the processing liquid supply 130 starts the supply of the processing liquid, a substrate holder 120 rotates the substrate W while holding the substrate W under the control of the controller 22. The processing liquid supply 130 starts the supply of the processing liquid to the substrate W according to the substrate processing condition that is set in the processing-condition-setting section 22a.

Step S106 includes measuring the abundance of the specific component of the substrate W. A component abundance meter 140 measures the abundance of the specific component of the substrate W. Typically, the component abundance meter 140 measures the abundance of the specific component of the substrate W with the processing liquid supply 130 supplying the processing liquid to the substrate W.

Step S108 includes acquiring a temporal change in the abundance of the specific component of the substrate W. Specifically, a temporal-change-acquiring section 22b acquires the temporal change in the abundance of the specific component of the substrate W. Typically, the component abundance meter 140 measures the abundance of the specific component of the substrate W more than once. Using the measurement results, the temporal-change-acquiring section 22b then acquires the temporal change in the abundance of the specific component. When the specific component of the substrate W is removed by a processing liquid, the abundance of the specific component of the substrate W decreases as the processing liquid is supplied.

Step S110 includes, based on the temporal change in the abundance of the specific component, creating a prediction line that predicts a temporal change in the specific component. Specifically, based on the temporal change in the abundance of the specific component, a prediction-line-creating section 22c creates a prediction line that predicts a temporal change in the specific component.

For example, the prediction-line-creating section 22c may create a prediction line from a predetermined relational expression based on the temporal change in the abundance of the specific component. Alternatively, the prediction-line-creating section 22c may enter the temporal change in the abundance of the specific component into a trained model LM and then acquire a prediction result of a temporal change in the specific component from the trained model LM to create a prediction line.

Step S112 includes changing the substrate processing condition. Specifically, a processing-condition-changing section 22d changes the substrate processing condition based on the prediction line.

Typically, the processing-condition-changing section 22d changes the substrate processing condition that is set in Step S102 for the substrate W currently being processed. However, the processing-condition-changing section 22d may change a processing condition for a substrate W to be processed in the future instead of the processing condition for the substrate W currently being processed.

Step S114 includes stopping the supply of the processing liquid to the substrate W. For example, the controller 22 continues the processing of the substrate W according to the substrate processing condition changed and ends the processing of the substrate W according to the substrate processing condition. In one example, the processing liquid supply 130 stops the supply of the processing liquid to the substrate W under the control of the controller 22. The substrate holder 120 subsequently stops rotating the substrate W under the control of the controller 22. In this manner, a process of substrate (W) processing ends.

In the present embodiment, the substrate W is processed under the substrate processing condition that is changed according to the characteristics of the substrate W. It is therefore possible to suppress, according to respective characteristics of substrates W, the occurrence of excessive or insufficient substrate processing condition.

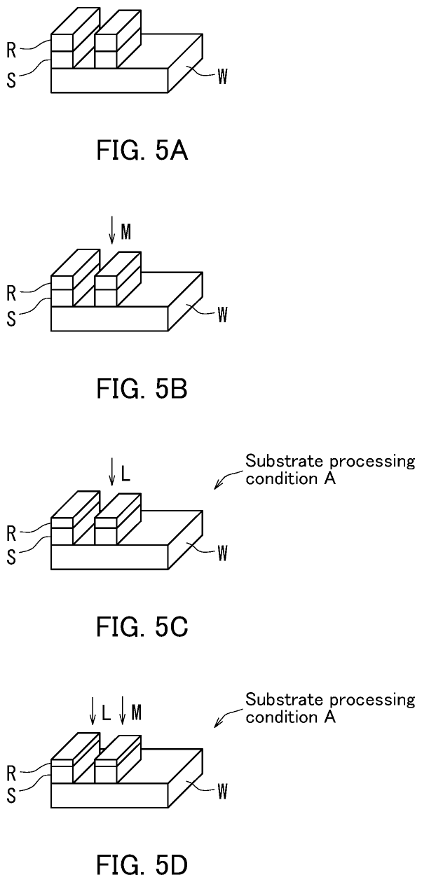

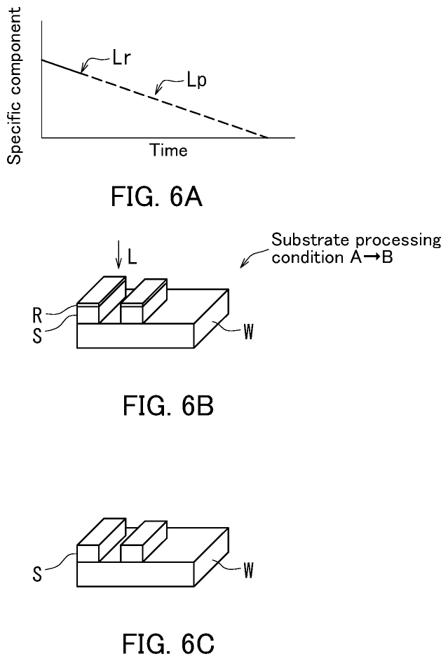

A substrate processing method according to the present embodiment will then be described with reference to FIGS. 1 to 6C. FIGS. 5A to 6C schematically illustrate the substrate processing method according to the present embodiment.

In a substrate W depicted in FIG. 5A, an object to be removed, R, exists on structure S. A substrate processing condition is set before processing of the substrate W is started. Specifically, a processing-condition-setting section 22a sets therein the substrate processing condition for the processing of the substrate W. For example, the processing-condition-setting section 22a reads recipe information stored in storage 24 and sets therein the substrate processing condition according to the recipe information.

As depicted in FIG. 5B, the abundance of a specific component, contained in the object to be removed, R, of the substrate W is measured. A component abundance meter 140 measures the abundance of the specific component in the object to be removed, R. Here, measurement of the abundance of the specific component by the component abundance meter 140 is referred to as Measurement M.

When the specific component exists uniformly in an object to be removed, the abundance of the specific component serves as an indicator of the abundance of the object to be removed, R. For example, the abundance of the specific component serves as an index of the thickness (height) of the object to be removed, R.

As depicted in FIG. 5C, supply of a processing liquid to the substrate W is started. Here, as the substrate processing condition, a substrate processing condition A is set. A processing liquid supply 130 supplies a processing liquid to the substrate W according to the substrate processing condition A. For example, the substrate W is supplied with the processing liquid and then the object to be removed, R, is gradually dissolved by the processing liquid. In this case, the thickness of the object to be removed, R, gradually decreases. Here, the supply of the processing liquid by the processing liquid supply 130 is indicated as Supply L.

As depicted in FIG. 5D, the abundance of the specific component, contained in the object to be removed, R, of the substrate W is measured while the substrate W is being supplied with the processing liquid. Specifically, the component abundance meter 140 performs Measurement M for measuring the abundance of the specific component of the substrate W while the processing liquid supply 130 is performing Supply L of the processing liquid to the substrate W according to the substrate processing condition A that is set.

The component abundance meter 140 measures the abundance of the specific component. The component abundance meter 140 may measure the abundance of the specific component at predetermined time intervals. Alternatively, the component abundance meter 140 may continuously measure the abundance of the specific component.

As depicted in FIG. 6A, a temporal-change-acquiring section 22b acquires a temporal change in the abundance of the specific component based on measurement results by the component abundance meter 140. In FIG. 6A, Actual measurement line Lr represents the temporal change in the abundance of the specific component acquired by the temporal-change-acquiring section 22b.

A prediction-line-creating section 22c predicts a temporal change in the specific component based on the temporal change in the abundance of the specific component acquired by the temporal-change-acquiring section 22b. The prediction-line-creating section 22c creates, based on the temporal change in the abundance of the specific component, a prediction line Lp that predicts a temporal change in the specific component. The prediction line Lp indicates a temporal change in the specific component when it is assumed that the processing of the substrate W is continued under the substrate processing condition A. In FIG. 6A, the prediction line Lp represents a temporal change in the specific component, created by the prediction-line-creating section 22c. Here, the prediction line Lp extends in the same straight line as Actual measurement line Lr.

The processing-condition-changing section 22d changes the substrate processing condition based on the prediction line Lp. Specifically, the processing-condition-changing section 22d changes the active substrate processing condition from the substrate processing condition A to a substrate processing condition B based on the prediction line Lp.

The processing-condition-changing section 22d changes the substrate processing condition based on the rate of the temporal change in the specific component indicated by the prediction line Lp. For example, the processing-condition-changing section 22d changes the substrate processing condition based on the magnitude of the slope of the prediction line Lp. Alternatively, the processing-condition-changing section 22d changes the substrate processing condition based on the time at which the specific component depicted on the prediction line Lp becomes zero.

The processing-condition-changing section 22d changes the substrate processing condition so that the temporal change in the specific component of the substrate W becomes slower when the temporal change in the specific component depicted by the prediction line Lp is faster than a temporal change previously assumed before the substrate W is processed (i.e., when the rate of change in the prediction line Lp is relatively large). Alternatively, the processing-condition-changing section 22d changes the substrate processing condition so that a processing liquid supply period becomes shorter when the time at which the specific component depicted by the prediction line Lp becomes zero is shorter than a processing end time expected for the substrate W.

Alternatively, the processing-condition-changing section 22d changes the substrate processing condition so that the temporal change in the specific component of the substrate W becomes faster when the temporal change in the specific component depicted by the prediction line Lp is slower than the temporal change previously assumed before the substrate W is processed (i.e., when the rate of change in the prediction line Lp is relatively small). Alternatively, the processing-condition-changing section 22d changes the substrate processing condition so that a processing liquid supply period becomes longer when the time at which the specific component depicted by the prediction line Lp becomes zero is longer than the processing end time expected for the substrate W.

Typically, the processing-condition-changing section 22d changes the parameter of at least one item of the substrate processing condition. For example, the processing-condition-changing section 22d changes a processing liquid supply period based on the temporal change in the abundance of the specific component. In one example, the processing-condition-changing section 22d shortens the processing liquid supply period based on the temporal change in the abundance of the specific component.

As depicted in FIG. 6B, the processing of the substrate W is continued according to the substrate processing condition B. Specifically, the controller 22 supplies a processing liquid to the substrate W and continues the processing of the substrate W. Here, an active substrate processing condition is set to the substrate processing condition B. The processing liquid supply 130 therefore supplies a processing liquid to the substrate W according to the substrate processing condition B. In one example, the processing liquid supply 130 continues the supply of the processing liquid until the end of the processing liquid supply period that has been shortened by changing the substrate processing condition.

As depicted in FIG. 6C, a process of substrate (W) processing is completed. The object to be removed, R, in the structure S can be removed by the processing of the substrate W. The structure S can be exposed.

The present embodiment acquires a prediction line Lp that predicts a temporal change in the specific component from the measurement results of the substrate W measured during the processing of the substrate W. The substrate processing condition is then changed based on the prediction line Lp acquired. The prediction line Lp is based on characteristics specific to the substrate W being processed. It is therefore possible to process the substrate W under a substrate processing condition in which the characteristics specific to the substrate W is taken into consideration.

Note that in FIG. 6A, the prediction line Lp extends in the same straight line as Actual measurement line Lr, but the present embodiment is not limited to this. The prediction line Lp may be created in a manner different from Actual measurement line Lr.

Note that in the above description with reference to FIGS. 5A to 6C, the object to be removed, R, of the structure S is removed by the processing liquid, but the present embodiment is not limited to this. An object to be removed, R, between structures S may be removed by a processing liquid. For example, after dry etching, the object to be removed, R, located between the structures S may be removed by the processing liquid.

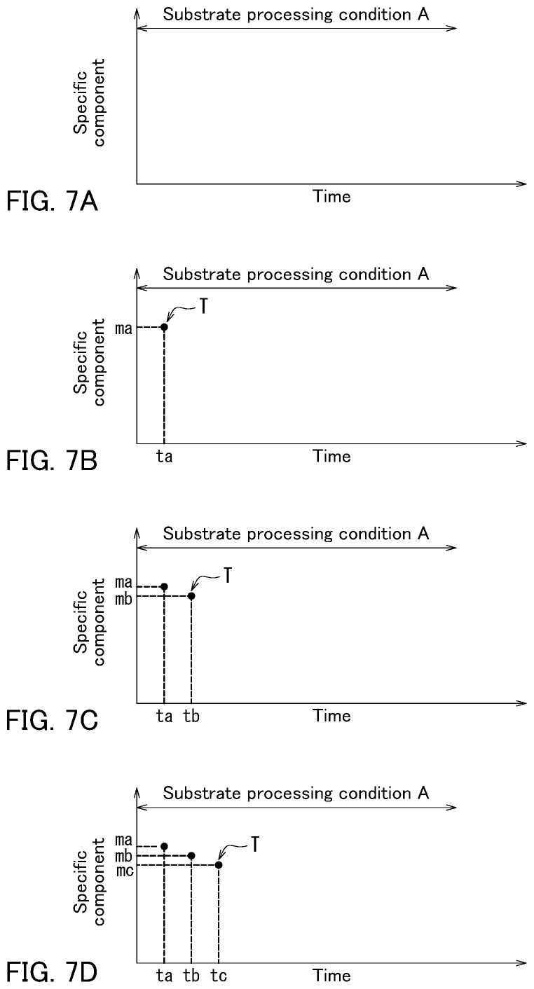

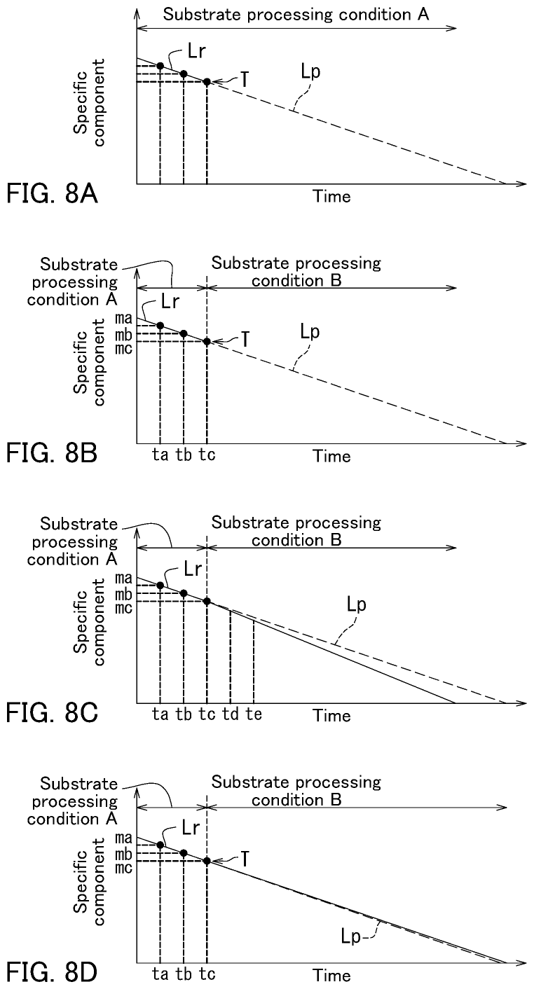

A substrate processing method according to the present embodiment will then be described with reference to FIGS. 1 to 8D. FIGS. 7A to 8D are graphs each of which depicts a temporal change in the abundance of a specific component of a substrate W in the substrate processing method according to the present embodiment. The horizontal axis and the vertical axis of each graph indicate time and the abundance of the specific component, respectively.

In FIG. 7A, a substrate processing condition A for the substrate W is set before the substrate W is processed with a processing liquid. Specifically, a processing-condition-setting section 22a sets therein the substrate processing condition A for processing the substrate W.

In FIG. 7B, the supply of the processing liquid to the substrate W is started and the processing of the substrate W is started according to the substrate processing condition A. The supply of the processing liquid to the substrate W is started and then the abundance of the specific component of the substrate W is measured. The abundance of the specific component is Abundance ma when Time ta has elapsed since the supply of the processing liquid to the substrate W was started. Here, the arrow T indicates time as a target.

In FIG. 7C, the processing of the substrate W is continued according to the substrate processing condition A with the supply of the processing liquid to the substrate W being continued. The abundance of the specific component is measured with the supply of the processing liquid to the substrate W being continued. The abundance of the specific component is Abundance mb (<ma) when Time tb (>ta) has elapsed since the supply of the processing liquid to the substrate W was started.

In FIG. 7D, the supply of the processing liquid to the substrate W is continued. The abundance of the specific component is measured with the supply of the processing liquid to the substrate W being continued. The abundance of the specific component is Abundance mc (<mb) when Time tc (>tb) has elapsed since the supply of the processing liquid to the substrate W was started.

In FIG. 8A, a temporal-change-acquiring section 22b acquires a temporal change in the abundance of the specific component based on measurement results by a component abundance meter 140. The temporal-change-acquiring section 22b acquires a temporal change in the abundance of the specific component from Abundance ma of the specific component at Time ta, Abundance mb of the specific component at Time tb, and Abundance mc of the specific component at Time tc. In this way, the temporal-change-acquiring section 22b acquires the temporal change in the abundance of the specific component based on the abundance of the specific component of the substrate W measured through the component abundance meter 140 at each point in a specific period of time within a processing liquid supply period. Here, the specific period of time is a period of time before the processing liquid supply 130 starts and then ends the supply of the processing liquid to the substrate W.

The temporal-change-acquiring section 22b may create Actual measurement line Lr indicating the temporal change in the abundance of the specific component. Actual measurement line Lr may be displayed on a display section. FIG. 6A depicts Actual measurement line Lr indicating the temporal change in the abundance of the specific component acquired by the temporal-change-acquiring section 22b.

A prediction line Lp that predicts the temporal change in the specific component is created based on the temporal change in the abundance of the specific component. Specifically, a prediction-line-creating section 22c creates a prediction line Lp based on the temporal change in the abundance of the specific component. The prediction-line-creating section 22c creates a prediction line Lp that predicts a temporal change in the abundance of the specific component of the substrate W after a specific period of time within the processing liquid supply period, based on the temporal change in the abundance of the specific component acquired by the temporal-change-acquiring section 22b.

Note that the prediction line Lp may be created based on Actual measurement line Lr. Typically, the prediction line Lp is created by extending Actual measurement line Lr. The prediction line Lp may be displayed on the display section together with or separately from Actual measurement line Lr.

In FIG. 8B, a processing-condition-changing section 22d changes the substrate processing condition based on the prediction line Lp that predicts the temporal change in the specific component. Specifically, the processing-condition-changing section 22d changes the substrate processing condition A to substrate processing condition B based on the prediction line Lp. For example, the processing-condition-changing section 22d changes at least one set value of a plurality of items that are set as the substrate processing condition A, thereby changing the substrate processing condition A to the substrate processing condition B.

In FIG. 8C, the processing of the substrate W is continued according to the substrate processing condition B. The processing of the substrate W is continued with the substrate W supplied with the processing liquid. Here, an active substrate processing condition is set to a substrate processing condition B. The processing liquid supply 130 therefore supplies the processing liquid to the substrate W according to the substrate processing condition B. In one example, the processing liquid supply 130 continues the supply of the processing liquid until the end of the processing liquid supply period that has been shortened by the change of the substrate processing condition.

In FIG. 8C, the temporal change in the specific component may be changed to be different from the prediction line Lp according to an active substrate processing condition being changed to the substrate processing condition B. For example, the temporal change in the specific component may proceed faster than the temporal change in the prediction line Lp according to the change of the substrate processing condition. In one example, the temporal change in the specific component may be changed to be larger than the temporal change in the prediction line Lp by increasing a flow rate, a concentration, and a temperature of the processing liquid or by decreasing a substrate rotation speed.

Alternatively, the temporal change in the specific component may proceed more slowly than the temporal change in the prediction line Lp according to the change of the substrate processing condition. In one example, the temporal change in the specific component may be changed to be smaller than the temporal change in the prediction line Lp by decreasing the flow rate, the concentration, and the temperature of the processing liquid or by increasing the substrate rotation speed.

In FIG. 8D, as the substrate processing condition A is changed to the substrate processing condition B, the temporal change in the specific component may vary according to the prediction line Lp instead of changing the temporal change in the specific component. In this case, preferably, the substrate W is processed until the abundance of the specific component becomes zero, according to the substrate processing condition changed. For example, substrate processing time may be changed according to the time at which the specific component in the prediction line Lp represents zero.

In the present embodiment, the substrate W is processed under the substrate processing condition that is changed based on the temporal change in the abundance of the specific component of the substrate W being processed. It is therefore possible to process the substrate W under the substrate processing condition according to the characteristics of the substrate W.

In FIGS. 7A to 8D, the abundance of the specific component decreases as time passes, but the present embodiment is not limited to this. The abundance of the specific component may increase as time passes.

In the present embodiment, the substrate processing condition for the substrate W are changed based on the temporal change in the abundance of the specific component of the substrate W being processed. When the substrate processing condition is changed, preferably substrate processing time is changed as the substrate processing condition.

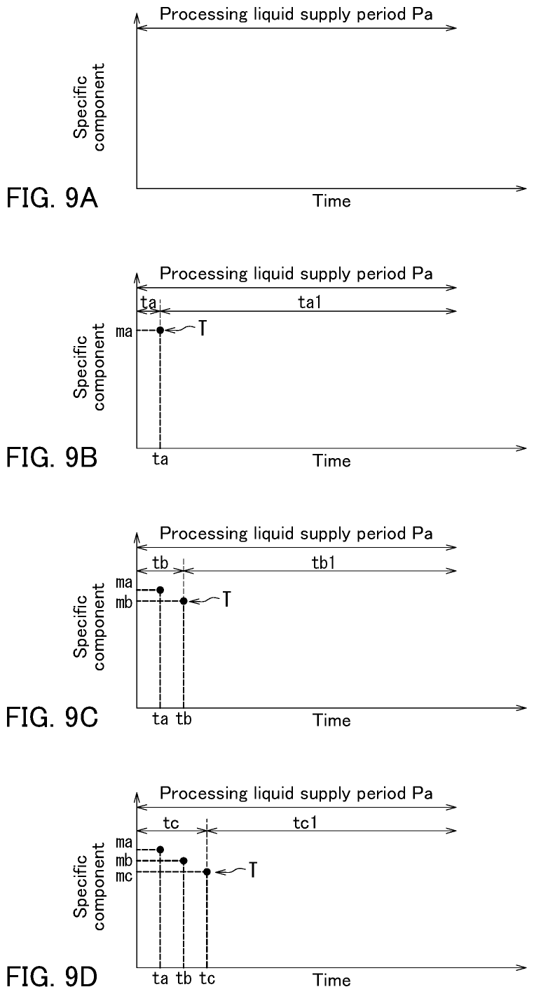

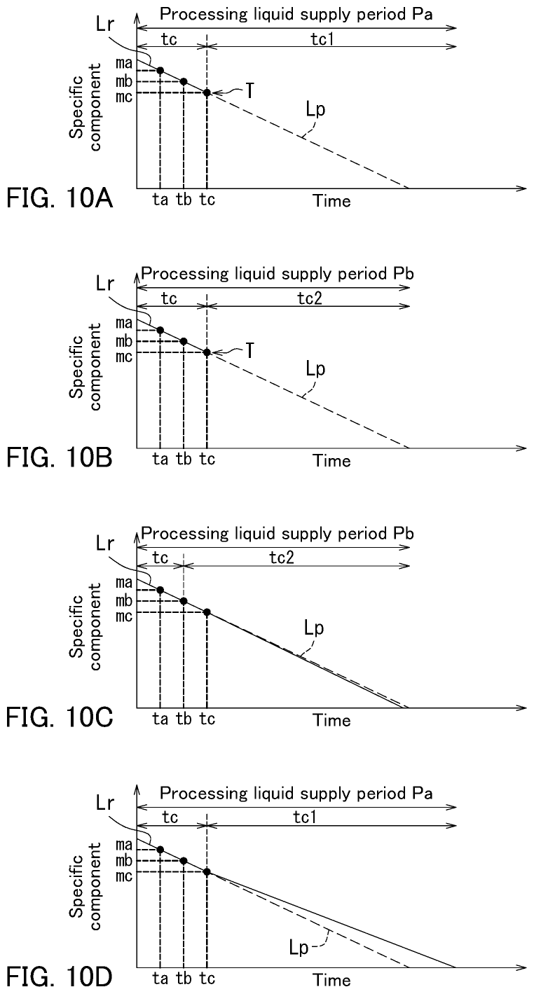

A substrate processing method according to the present embodiment will then be described with reference to FIGS. 1 to 10D. FIGS. 9A to 10D are graphs each of which depicts a temporal change in the abundance of the substrate W, in the substrate processing method according to the present embodiment. The horizontal axis and the vertical axis of each graph indicate time and abundance, respectively.

In FIG. 9A, a processing liquid supply period Pa during which a substrate W is supplied with a processing liquid is set before the supply of the processing liquid to the substrate W is started. Specifically, a processing-condition-setting section 22a sets a processing liquid supply period to the processing liquid supply period Pa when a substrate processing condition is set.

In FIG. 9B, the supply of the processing liquid to the substrate W is started. After the supply of the processing liquid to the substrate W is started, the abundance of a specific component is measured. The abundance of the specific component is Abundance ma when Time ta has elapsed since the supply of the processing liquid to the substrate W was started.

At this time, the processing liquid is set to be supplied over the processing liquid supply period Pa. Here, Time ta has elapsed since the supply of the processing liquid was started. At a setting, the processing liquid is then continuously supplied for a period of time, ta1 (=Pa−ta).

In FIG. 9C, the supply of the processing liquid to the substrate W is continued. The abundance of the specific component is measured with the supply of the processing liquid to the substrate W being continued. The abundance of the specific component is Abundance mb (<ma) when Time tb (>ta) has elapsed since the supply of the processing liquid to the substrate W was started.

Here, the processing liquid is also set to be supplied over the processing liquid supply period Pa. At this time, Time tb has elapsed since the supply of the processing liquid was started. At a setting, the processing liquid is then continuously supplied for a period of time, tb1 (=Pa−tb).

In FIG. 9D, the supply of the processing liquid to the substrate W is continued. The abundance of the specific component is measured with the supply of the processing liquid to the substrate W being continued. The abundance of the specific component is Abundance mc (<mb) when Time tc (>tb) has elapsed since the supply of the processing liquid to the substrate W was started.

Here, the processing liquid is also set to be supplied over the processing liquid supply period Pa. At this time, Time tc has elapsed since the supply of the processing liquid was started. At a setting, the processing liquid is then continuously supplied for a period of time, tc1 (=Pa−tc).

In FIG. 10A, a temporal-change-acquiring section 22b acquires a temporal change in the abundance of the specific component based on measurement results by a component abundance meter 140. The temporal-change-acquiring section 22b acquires the temporal change in the abundance of the specific component from Abundance ma of the specific component at Time ta, Abundance mb of the specific component at Time tb, and Abundance mc of the specific component at Time tc.

A prediction line Lp that predicts a temporal change in the specific component is created based on the temporal change in the abundance of the specific component. Specifically, based on the temporal change in the abundance of the specific component, a prediction-line-creating section 22c creates the prediction line Lp. The prediction line Lp may be created based on Actual measurement line Lr.

In FIG. 10B, a processing-condition-changing section 22d changes the processing liquid supply period based on the prediction line Lp that predicts the temporal change in the specific component. Specifically, the processing-condition-changing section 22d changes the processing liquid supply period Pa to a processing liquid supply period, Pb, based on the prediction line Lp.

The processing liquid is therefore set to be supplied over the processing liquid supply period, Pb. At this time, Time tc has elapsed since the supply of the processing liquid was started. At a setting, the processing liquid is then continuously supplied for a period of time, tc2 (=Pb−tc).

In FIG. 10C, the processing of the substrate W is continued according to the processing liquid supply period, Pb. The processing of the substrate W is continued with the substrate W supplied with the processing liquid. Here, the processing liquid supply period, Pb, is set as the substrate processing condition. A processing liquid supply 130 supplies the processing liquid to the substrate W according to the processing liquid supply period, Pb. In one example, the processing liquid supply 130 continues the supply of the processing liquid until the end of the processing liquid supply period that has been shortened according to the change of the substrate processing condition.

In FIG. 10D, based on the prediction line Lp, the substrate processing condition may be changed so that the processing liquid supply period Pa is not changed. For example, the processing liquid supply period may be adjusted to the processing liquid supply period Pa by processing under a substrate processing condition A until Time tc elapses since the supply of the processing liquid was started and then by processing under a substrate processing condition B after Time tc elapses.

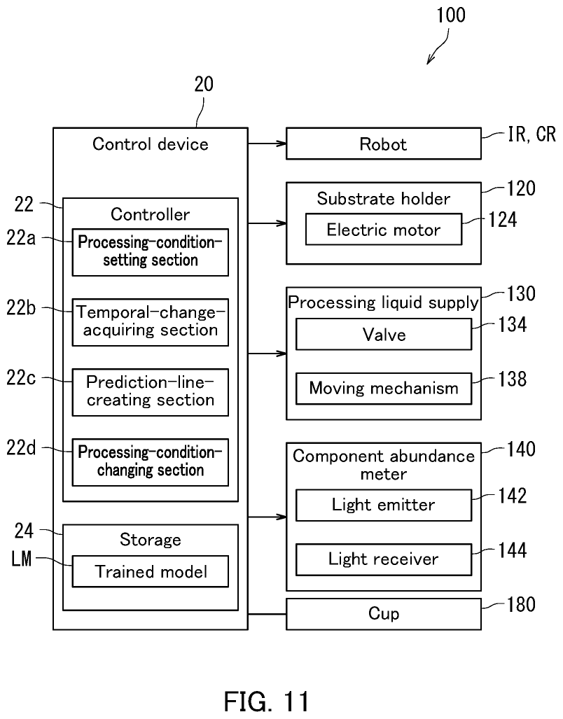

A substrate processing apparatus 100 according to the present embodiment will then be described with reference to FIGS. 1 to 11. FIG. 11 is a block diagram of the substrate processing apparatus 100 according to the present embodiment. The substrate processing apparatus 100 in FIG. 11 includes the same configuration as the substrate processing apparatus 100 described above with reference to FIG. 3, except that storage 24 stores a trained model LM. Duplicate descriptions are omitted to avoid redundancy.

As depicted in FIG. 11, the substrate processing apparatus 100 according to the present embodiment includes the storage 24 that stores the trained model LM. The trained model LM is built through machine learning from learning data that contains a processing condition and processing results with respect to a substrate to be learned. Here, the processing condition and the processing results are associated with each other. A controller 22 changes a substrate processing condition using the trained model LM stored in the storage 24.

Input information is on a temporal change in the abundance of a specific component acquired by a temporal-change-acquiring section 22b is entered into the trained model LM. The trained model LM then outputs output information on a prediction line that predicts a temporal change in the specific component.

A processing-condition-changing section 22d changes the substrate processing condition based on the output information obtained by entering input information into the trained model LM. Here, the input information is on the temporal change in the abundance of the specific component acquired by the temporal-change-acquiring section 22b. For example, the processing-condition-changing section 22d changes a processing liquid supply period based on output information on a prediction line acquired from the trained model LM by entering, into the trained model LM, input information on a temporal change in the abundance of a specific component of a substrate W. In one example, the processing-condition-changing section 22d shortens the processing liquid supply period in the substrate processing condition that is set in a processing-condition-setting section 22a, based on the output information.

The processing-condition-changing section 22d changes a substrate processing condition A to a substrate processing condition B based on the prediction line. For example, the processing-condition-changing section 22d changes at least one set value of a plurality of items that are set as the substrate processing condition A, thereby changing the substrate processing condition A to the substrate processing condition B.

In the above description, the processing-condition-changing section 22d changes the substrate processing condition for the substrate W based on the output information on the prediction line acquired from the trained model LM through a prediction-line-creating section 22c. The processing-condition-changing section 22d may however enter the output information acquired from the trained model LM into a different trained model LM to acquire substrate processing condition change information from the different trained model LM.

Note that the substrate processing apparatus 100 depicted in FIG. 11 includes the storage 24 that stores the trained model LM, but the present embodiment is not limited to this. Instead of the storage 24 storing the trained model LM, a server that can communicate with the substrate processing apparatus 100 may store the trained model LM. The processing-condition-changing section 22d may change the substrate processing condition based on output information from the trained model LM stored in the server.

The substrate processing apparatus 100 depicted in FIG. 11 changes the substrate processing condition based on the output information acquired from the trained model LM. For example, the trained model LM may output, as the output information, substrate processing condition change information on a substrate processing condition changed.

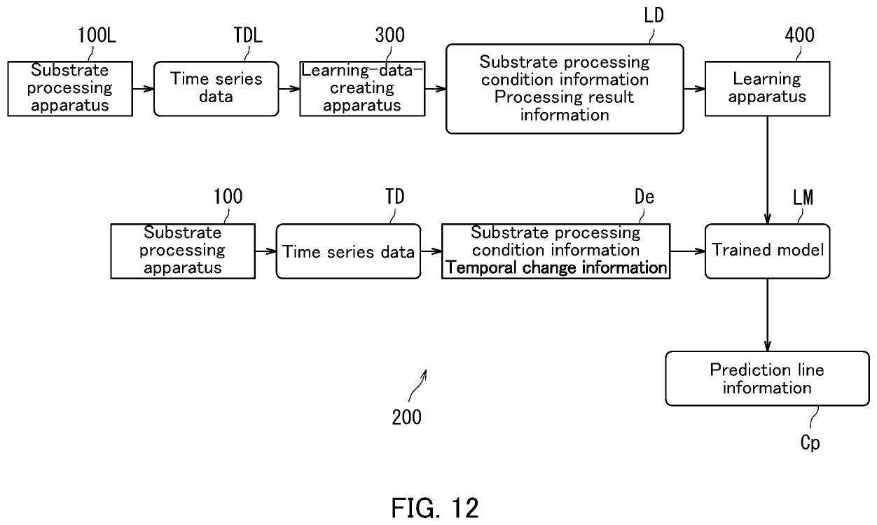

A substrate-processing-learning system 200 will then be described with reference to FIG. 12. Using the substrate-processing-learning system 200, how to build a trained model LM and input information and output information for the trained model LM will be described. FIG. 12 is a schematic diagram of the substrate-processing-learning system 200.

As depicted in FIG. 12, the substrate-processing-learning system 200 includes a substrate processing apparatus 100, a substrate processing apparatus 100L, a learning-data-creating apparatus 300, and a learning apparatus 400. Note that the learning-data-creating apparatus 300 and/or the learning apparatus 400 may be separate from the substrate processing apparatus 100 and/or the substrate processing apparatus 100L. Alternatively, the learning-data-creating apparatus 300 and/or the learning apparatus 400 may be installed in the substrate processing apparatus 100 and/or the substrate processing apparatus 100L.

The substrate processing apparatus 100 processes a substrate to be processed. Here, the substrate to be processed is provided with a pattern of structures, and the substrate processing apparatus 100 processes the substrate to be processed with a processing liquid. Note that the substrate processing apparatus 100 may perform processing other than the supply of the processing liquid with respect to the substrate to be processed. Typically, the substrate to be processed is shaped like a disk.

The substrate processing apparatus 100L processes a substrate to be learned. Here, the substrate to be learned is provided with a pattern of structures, and the substrate processing apparatus 100L processes the substrate to be learned with a processing liquid. Note that the substrate processing apparatus 100L may perform processing other than the supply of the processing liquid with respect to the substrate to be learned. The configuration of the substrate to be learned is the same as the configuration of the substrate to be processed. Typically, the substrate to be learned is shaped like a disk. The configuration of the substrate processing apparatus 100L is the same as the configuration of the substrate processing apparatus 100. The substrate processing apparatus 100L may be the same as the substrate processing apparatus 100. For example, the same substrate processing apparatus may process a substrate to be learned, and subsequently process a substrate to be processed. Alternatively, the substrate processing apparatus 100L may be another product having the same configuration as the substrate processing apparatus 100.

In the following description of the specification, a substrate to be learned may be described as a “substrate to be learned, WL”, and a substrate to be processed may be described as a “substrate to be processed, Wp”. The substrate to be learned, WL, and the substrate to be processed, Wp, may be referred to as a “substrate W” when there is no need to distinguish between the substrate to be learned, WL, and the substrate to be processed, Wp.

The substrate processing apparatus 100L outputs time series data TDL. The time series data TDL is on a temporal change in a physical quantity in the substrate processing apparatus 100L. The time series data TDL is on a temporal change in a physical quantity (value) that changes in time series over a predetermined period. For example, the time series data TDL is data on a temporal change in a physical quantity about processing performed, by the substrate processing apparatus 100L, on a substrate to be learned. Alternatively, the time series data TDL is data on a temporal change in a physical quantity about the characteristics of a substrate to be learned which has been processed by the substrate processing apparatus 100L. The time series data TDL may also include data on a manufacturing process before a substrate to be learned is processed by the substrate processing apparatus 100L.

Note that the values depicted in the time series data TDL may be values directly measured with a measuring instrument. Alternatively, the values depicted in the time series data TDL may be values obtained by calculating values directly measured with a measuring instrument. The values depicted in the time series data TDL may also be obtained by calculating values measured through a plurality of measuring instruments.

The learning-data-creating apparatus 300 creates learning data LD based on the time series data TDL or at least part of the time series data TDL. The learning-data-creating apparatus 300 outputs the learning data LD.

The learning data LD contains substrate processing condition information and processing result information, about the substrate to be learned, WL. In the learning data LD, the substrate processing condition information about the substrate to be learned, WL, is associated with the processing result information about the same.

The substrate processing condition information about the substrate to be learned, WL, is on a substrate processing condition performed on the substrate to be learned, WL. The substrate processing condition includes at least one of parameters which include: a flow rate, a concentration, and a temperature of the processing liquid for processing the substrate to be learned, WL; a substrate rotation speed at which the substrate to be learned, WL, rotates; and a processing liquid supply period during which a processing liquid is supplied.

The processing result information about the substrate to be learned, WL, is on the results of substrate processing performed on the substrate to be learned, WL. The processing result information contains temporal change information obtained by measuring a temporal change in the abundance of a specific component of the substrate to be learned, WL, according to the substrate processing condition. The temporal change information about the substrate to be learned, WL, is on a temporal change in the abundance of the specific component of the substrate to be learned, W. Typically, the temporal change information about the substrate to be learned, WL, is preferably on results measured over time indicating that the abundance of the specific component of the substrate to be learned, WL, has sufficiently shifted to a constant value. For example, the temporal change information about the substrate to be learned, WL, is preferably on results measured over time indicating that the specific component of the substrate to be learned, WL, has been sufficiently removed. Note that the processing result information may contain an evaluation result of the substrate to be learned, WL.

The learning apparatus 400 performs machine learning from learning data LD, thereby building a trained model LM. The learning apparatus 400 outputs the trained model LM.

The learning apparatus 400 stores a learning program. The learning program provides a machine learning algorithm for finding a certain rule from pieces of learning data LD and building a trained model LM expressing the rule found. The learning apparatus 400 executes the learning program, performs machine learning from the learning data LD, and adjusts the parameters of an inference program, thereby building the trained model LM.

For example, the machine learning algorithm is a supervised learning algorithm. Examples of the machine learning algorithm include a decision tree, the nearest neighbour algorithm, a naive Bayes classifier, a support vector machine, and artificial neural networks. The trained model LM therefore contains a decision tree, the nearest neighbour algorithm, a naive Bayes classifier, a support vector machine, or artificial neural networks. Backpropagation may be used for the machine learning building the trained model LM.

For example, the artificial neural network includes an input layer, one or more hidden layers, and an output layer. Specific examples of the artificial neural network include a deep neural network (DNN), a recurrent neural network (RNN), and a convolutional neural network (CNN). The artificial neural network accordingly performs deep learning. For example, the deep neural network includes an input layer, multiple hidden layers, and an output layer.

The substrate processing apparatus 100 outputs time series data TD. The time series data TD is on a temporal change in a physical quantity in the substrate processing apparatus 100. The time series data TD is on a temporal change in a physical quantity (value) that changes in time series over a predetermined period. For example, the time series data TD is on a temporal change in a physical quantity about processing performed, by the substrate processing apparatus 100, on a substrate to be processed. Alternatively, the time series data TD is on a temporal change in a physical quantity about the characteristics of a substrate to be processed which has been processed by the substrate processing apparatus 100.

Note that the values depicted in the time series data TD may be values directly measured with a measuring instrument. Alternatively, the values depicted in the time series data TD may be values obtained by calculating values directly measured with a measuring instrument. The values depicted in the time series data TD may also be obtained by calculating values measured through a plurality of measuring instruments. The time series data TD may contain data on a manufacturing process before the substrate to be processed is processed by the substrate processing apparatus 100.

An object used by the substrate processing apparatus 100 corresponds to an object possessed by the substrate processing apparatus 100L. The structure of the object possessed by the substrate processing apparatus 100 is the same as the structure of the object possessed by the substrate processing apparatus 100L. In the time series data TD, a physical quantity of the object possessed by the substrate processing apparatus 100 corresponds to a physical quantity of the object possessed by the substrate processing apparatus 100L. The physical quantity of the object possessed by the substrate processing apparatus 100L is therefore the same as the physical quantity of the object possessed by the substrate processing apparatus 100.

Input information De about a substrate to be processed, Wp, is created from the time series data TD. The input information De about the substrate to be processed, Wp, contains substrate processing condition information and temporal change information, about the substrate to be processed, Wp. The substrate processing condition information about the substrate to be processed, Wp, is on a substrate processing condition under which the processing of the substrate to be processed, Wp, is started. The temporal change information is on a temporal change in the abundance of the specific component of the substrate to be processed, Wp. Here, the temporal change is acquired from the substrate to be processed, Wp, which has been started to be processed. Note that the substrate processing condition for the substrate to be processed, Wp, may be fixed. In this case, the input information De may contain temporal change information without containing the substrate processing condition information about the substrate to be processed, Wp.

The trained model LM is supplied with the input information De about the substrate to be processed, Wp, and then outputs prediction line information Cp on a substrate processing condition suitable for the processing of the substrate to be processed, Wp. The prediction line information Cp is on a substrate processing condition for change. The prediction line information Cp is used in the substrate processing apparatus 100 that processes the substrate to be processed, Wp.

Specifically, a processing-condition-changing section 22d enters input information to the trained model LM to acquire prediction line information Cp from the trained model LM. Here, the input information is on a substrate processing condition A and a temporal change in the abundance of the specific component acquired by a temporal-change-acquiring section 22b. The processing-condition-changing section 22d changes a processing liquid supply condition based on the prediction line information Cp.

For example, the processing-condition-changing section 22d changes a processing liquid supply period based on the prediction line information Cp. In one example, the processing-condition-changing section 22d changes a setting value of an item indicating the processing liquid supply period from a processing liquid supply period Pa to a processing liquid supply period, Pb, while maintaining setting values of items other than the item corresponding to the processing liquid supply period.

As described with reference to FIG. 12, the learning apparatus 400 performs machine learning. A trained model LM with high accuracy can therefore be built from time series data TDL which is extremely complex and has a huge amount of analysis targets. The trained model LM is supplied with input information De from time series data TD about a substrate to be processed, Wp, and then outputs prediction line information Cp on a temporal change in the specific component. The processing-condition-changing section 22d changes the substrate processing condition for the substrate to be processed, Wp, based on the prediction line information Cp. As described above, the substrate to be processed, Wp, can be processed under the substrate processing condition according to the characteristics of the substrate to be processed, Wp.

Note that in the description given above with reference to FIGS. 1 to 12, the substrate processing apparatus 100 mainly changes the substrate processing condition for the substrate W being processed but the present embodiment is not limited to this. The substrate processing apparatus 100 may change substrate processing condition for a substrate W to be processed in the future.

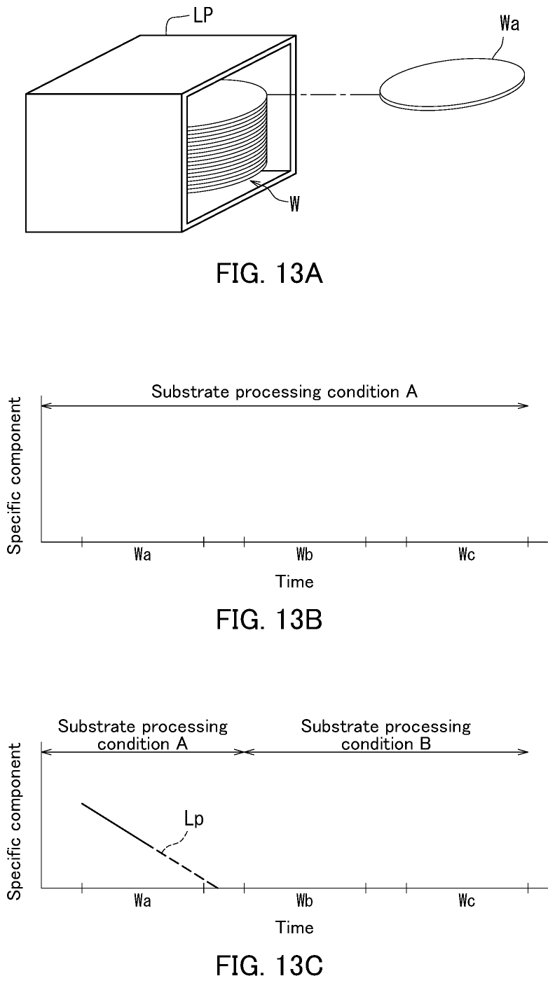

A substrate processing method according to the present embodiment will then be described with reference to FIGS. 1 to 13C. FIG. 13A is a schematic diagram depicting a plurality of substrates W of the same lot in the substrate processing method according to the present embodiment. FIGS. 13B and 13C are graphs each of which depicts a temporal change in the abundance of a substrate W in the substrate processing method according to the present embodiment.

As depicted in FIG. 13A, one substrate W is taken out from the plurality of substrates included in the same lot and then processed. Here, a substrate Wa is taken out from the plurality of substrates W of the same lot housed in the load port LP. Typically, substrates W within the same lot exhibit similar characteristics.

In FIG. 13B, a substrate processing condition is set for the plurality of substrates W. Specifically, a processing-condition-setting section 22a sets the substrate processing condition for the plurality of substrates W. Here, the processing-condition-setting section 22a sets a substrate processing condition A under which each of substrates Wa to Wc is processed with substrate Wa, substrate Wb, and substrate Wc being processed in this order.

In FIG. 13C, the supply of a processing liquid is started according to the substrate processing condition A. A processing liquid supply 130 starts the supply of the processing liquid to the substrate Wa under the control of a controller 22. The processing liquid supply 130 starts the supply of the processing liquid to the substrate Wa according to the substrate processing condition A that is set in the processing-condition-setting section 22a.

A substrate processing apparatus 100 measures the abundance of a specific component of the substrate Wa being processed. Specifically, a component abundance meter 140 measures the abundance of the specific component of the substrate Wa. Typically, the component abundance meter 140 measures the abundance of the specific component of the substrate Wa with the processing liquid supply 130 supplying the processing liquid to the substrate Wa.

The substrate processing apparatus 100 acquires a temporal change in the abundance of the specific component of the substrate Wa. Specifically, a temporal-change-acquiring section 22b acquires the temporal change in the abundance of the specific component of the substrate Wa. Typically, the component abundance meter 140 measures the abundance of the specific component of the substrate Wa more than once. Using the measurement results, the temporal-change-acquiring section 22b then acquires a temporal change in the abundance of the specific component of the substrate Wa.

A prediction line is subsequently created based on the temporal change in the abundance of the specific component. Here, the prediction line predicts a temporal change in the specific component. Specifically, based on the temporal change in the abundance of the specific component, a prediction-line-creating section 22c creates a prediction line that predicts a temporal change in the specific component. For example, the prediction-line-creating section 22c may create a prediction line by creating an approximate expression that linearly interpolates the temporal change in the abundance of the specific component. Alternatively, the prediction-line-creating section 22c may create a prediction line from a trained model.

The substrate processing condition is subsequently changed based on the prediction line acquired with respect to the substrate Wa. Specifically, a processing-condition-changing section 22d changes a substrate processing condition for the substrates Wb and Wc to be processed later, based on the prediction line for the substrate Wa. In this way, the processing-condition-changing section 22d changes the substrate processing condition A previously set for the substrates Wb and Wc to a substrate processing condition B.

Note that the processing-condition-changing section 22d may change a substrate processing condition for the substrate Wa while the substrate Wa is being processed. In this case, the substrate processing condition changed for the substrate Wa may be different from the substrate processing condition for the substrates Wb and Wc to be processed later.

The processing-condition-changing section 22d may change the substrate processing condition for the substrate Wb before the supply of a processing liquid to the substrate Wb is started. The processing-condition-changing section 22d may change the substrate processing condition for the substrate Wb before the supply of the processing liquid to the substrate Wb is ended.

Similarly, the processing-condition-changing section 22d may change the substrate processing condition for the substrate Wc before the supply of a processing liquid to the substrate Wc is started. The processing-condition-changing section 22d may change the substrate processing condition for the substrate Wc before the supply of the processing liquid to the substrate Wc is ended.

Substrates W included in the same lot exhibit similar characteristics. Therefore, the processing-condition-changing section 22d may change the substrate processing condition for a substrate W to be processed later, instead of the substrate processing condition for a substrate W currently being processed. It is therefore possible to process substrates W under a substrate processing condition according to the characteristics of each substrate W.

As above, the embodiments of the present invention have been described with reference to the drawings. However, the present invention is not limited to the above-described embodiments and can be practiced in various ways within the scope without departing from the essence of the present invention. Constituent elements disclosed in the above embodiments can be combined as appropriate in various different inventive forms. For example, some constituent elements may be omitted from all of the constituent elements described in the embodiments. Alternatively or additionally, constituent elements described in different embodiments may be combined as appropriate. The drawings mainly illustrate schematic constituent elements in order to facilitate understanding of the invention, and thickness, length, numbers, intervals or the like of each constituent element illustrated in the drawings may differ from actual ones thereof in order to facilitate preparation of the drawings. Further, the material, shape, or dimensions of each constituent element or the like described in the above embodiments is merely an example that does not impose any particular limitations and may be altered in various ways as long as such alterations do not substantially deviate from the effects of the present invention.

### INDUSTRIAL APPLICABILITY

The present invention is suitably used for a substrate processing apparatus and a substrate processing method.

### REFERENCE SIGNS LIST

100 Substrate processing apparatus
110 Chamber
120 Substrate holder
130 Processing liquid supply
140 Component abundance meter
W Substrate

1. A substrate processing apparatus, comprising:
a substrate holder that holds a substrate;
a processing liquid supply that supplies a processing liquid to the substrate;
a component abundance meter that measures abundance of a specific component of the substrate; and
a controller that controls the substrate holder, the processing liquid supply, and the component abundance meter, wherein
the controller includes:
a temporal-change-acquiring section that acquires a temporal change in the abundance of the specific component based on the abundance of the specific component of the substrate measured through the component abundance meter during a specific period of time within a processing liquid supply period, the processing liquid supply period being a period of time from start to end of supply of the processing liquid to the substrate by the processing liquid supply;
a prediction-line-creating section that creates a prediction line based on a temporal change in the abundance of the specific component acquired by the temporal-change-acquiring section, the prediction line predicting a temporal change in the abundance of the specific component of the substrate after the specific period of time within the processing liquid supply period; and
a processing-condition-changing section that changes a substrate processing condition, under which a specific substrate that is the substrate or a substrate is processed, based on the prediction line before the supply of the processing liquid is stopped.

2. The substrate processing apparatus according to claim 1, wherein the component abundance meter measures the abundance of the specific component of the substrate using infrared light.

3. The substrate processing apparatus according to claim 1, wherein the processing-condition-changing section changes the substrate processing condition, under which the specific substrate is processed, based on a substrate processing condition and processing results with respect to a substrate to be learned.

4. The substrate processing apparatus according to claim 3, wherein the processing-condition-changing section changes the substrate processing condition, under which the specific substrate is processed, through a trained model, the trained model being built through machine learning from learning data that contains the substrate processing condition and the processing results with respect to the substrate to be learned, the substrate processing condition and the processing results being associated with each other.

5. The substrate processing apparatus according to claim 1, wherein the processing-condition-changing section changes the processing liquid supply period, during which the processing liquid supply supplies the processing liquid, based on the temporal change in the abundance of the specific component acquired by the temporal-change-acquiring section.

6. The substrate processing apparatus according to claim 5, wherein the processing-condition-changing section shortens the processing liquid supply period based on the temporal change in the abundance of the specific component acquired by the temporal-change-acquiring section.

7. The substrate processing apparatus according to claim 1, wherein the processing-condition-changing section changes, based on the temporal change in the abundance of the specific component acquired by the temporal-change-acquiring section, any of: a flow rate, a concentration, and a temperature of the processing liquid for processing the specific substrate; a substrate rotation speed at which the specific substrate is rotated by the substrate holder; and the processing liquid supply period during which the processing liquid is supplied.

8. The substrate processing apparatus according to claim 1, wherein the processing-condition-changing section changes the substrate processing condition, under which the specific substrate is processed, with the processing liquid supply continuing the supply of the processing liquid.

9. The substrate processing apparatus according to claim 1, wherein the processing-condition-changing section changes the substrate processing condition, under which a different substrate is processed, based on the temporal change in the abundance of the specific component acquired by the temporal-change-acquiring section, the different substrate being different from the substrate from which the temporal-change-acquiring section has acquired the abundance of the specific component.

10. A substrate processing method, comprising:
measuring abundance of a specific component of a substrate during a specific period of time within a processing liquid supply period, the processing liquid supply period being a period of time from start to end of supply of a processing liquid to the substrate;
acquiring a temporal change in the abundance of the specific component based on the abundance of the specific component of the substrate measured in the measuring;
creating a prediction line based on a temporal change in the abundance of the specific component acquired in the acquiring, the prediction line predicting a temporal change in the abundance of the specific component of the substrate after the specific period of time within the processing liquid supply period; and
changing a substrate processing condition, under which a specific substrate that is the substrate or a substrate is processed, based on the prediction line before the supply of the processing liquid is stopped.
